(19) United States
(12) Patent Application Publication
(10) Pub. No.: US 2009/0212862 A1
(43) Pub. Date: Aug. 27, 2009

(54) OP-AMP CIRCUIT AND OP-AMP CIRCUIT DRIVING METHOD

(75) Inventor: Ryuuta KUROKI, Miyazaki (JP)

Correspondence Address: Studebaker & Brackett PC, 1890 Preston White Drive, Suite 105, Reston, VA, 20191, US

(73) Assignee: OKI SEMICONDUCTOR CO., LTD., Tokyo (JP)

(21) Appl. No.: 12/358,556

(22) Filed: Jan. 23, 2009

(30) Foreign Application Priority Data
Feb. 25, 2008 (JP) 2008-043169

(51) Int. Cl. H03F 3/45

(52) U.S. Cl. 330/253

(57) ABSTRACT

The present invention is to provide a CMOS op-amp circuit, an op-amp circuit and an op-amp circuit control method that can increase operating speed when the op-amp circuit stabilizes to a steady state after release of a power down state. During power down, a voltage is applied to a node N1 by SW1, and the voltage is outputted from an output end OUT1. Accordingly, an electric potential difference arises between electrodes of a phase compensation capacitor C1, and the electric charge can be accumulated in the phase compensation capacitor C1. When the op-amp circuit switches to a steady state, the electric charge that had been accumulated is discharged, and a gate of an N-channel MOS transistor TN3 switches ON. Accordingly, the output value of an output end OUT2 is instantaneously reduced and becomes stable.

### CROSS-REFERENCE TO RELATED APPLICATION

This application claims priority under 35 USC 119 from Japanese Patent Application No. 2008-043169, the disclosure of which is incorporated by reference herein.

### BACKGROUND OF THE INVENTION

1. Field of the Invention

The present invention relates to an op-amp (operational amplifier) circuit and an op-amp circuit control method. The present invention particularly relates to a CMOS op-amp circuit that includes a power down (low power consumption) function and a CMOS op-amp circuit driving method.

2. Description of the Related Art

Commonly, there are known CMOS op-amp circuits that include a power down function, where the CMOS op-amp circuit operates in a low power consumption state in the case of a standby state or a sleep mode for the purpose of reducing power consumption (e.g., see JP-A No. 5-324139 and JP-A No. 10-262336).

FIG. 11 is a configurational diagram showing an example of a common CMOS op-amp circuit 50 to which a power down function has been given. Further, FIG. 12 shows an example of an amplifier circuit that uses the CMOS op-amp circuit 50. The CMOS op-amp circuit 50 shown in FIG. 11 reaches steady operation when the input value of an enable signal is an “H” level. Further, the CMOS op-amp circuit 50 shown in FIG. 11 reaches a power down state when the input value of the enable signal is an “L” level. During the steady operation, a differential amp operates in accordance with differential inputs Vin− and Vin+ and the input value of a bias. Further, during power down, supply of electrical power to the differential amp is cut and the output value is fixed to a level of VDD1.

However, in the PMOS differential CMOS op-amp circuit 50 of FIG. 11, when the input value of the enable signal is changed from an “L” level to an “H” level to release the power down state, the op-amp starts operation in accordance with the state of the differential inputs Vin− and Vin+. However, when the op-amp drives a large-capacity load (a large-capacity load 56 in FIG. 12), a considerable time is required until the op-amp becomes stable. Consequently, in order to shorten the time until the op-amp becomes stable and to increase speed, it has been necessary to enlarge the dimension (size) of the transistors.

### SUMMARY OF THE INVENTION

The present invention provides, in a CMOS op-amp circuit, an op-amp circuit and an op-amp circuit driving method that can increase operating speed until the op-amp circuit stabilizes to a steady state after release of a power down state.

A first aspect of the invention is an op-amp circuit including: a differential amp; a CMOS output circuit; a phase compensation capacitor disposed between an output end of the differential amp and the CMOS output circuit; and a switching element disposed between the phase compensation capacitor and a power supply that supplies a charging voltage for charging the phase compensation capacitor, wherein the switching element applies the charging voltage from the power supply to the output end of the differential amp when an inputted switching signal represents a power down state of the differential amp, and stops the application of the charging voltage to the output end of the differential amp when the inputted switching signal represents a steady operation state.

In a second aspect of the present invention, in the above-described first aspect, the CMOS output circuit may include an output switch element including a gate terminal connected to the output end of the differential amp and a drain terminal connected to a side that outputs an output voltage that is different from the charging voltage and to the CMOS output circuit side of the phase compensation capacitor, and the charging voltage may be lower than the output voltage.

In a third aspect of the present invention, in the above-described first aspect, may further include a resistor connected between the phase compensation capacitor and the differential amp, the CMOS output circuit may include an output switch element including a gate terminal connected to the output end of the differential amp and a drain terminal connected to a side that outputs an output voltage that is different from the charging voltage and to the CMOS output circuit side of the phase compensation capacitor, and the charging voltage and the output voltage may be the same.

A fourth aspect of the invention is a method of driving an op-amp circuit that includes a differential amp, a CMOS output circuit, a phase compensation capacitor disposed between an output end of the differential amp and the CMOS output circuit, and a switching element disposed between the phase compensation capacitor and a power supply that supplies a charging voltage for charging the phase compensation capacitor, the method including: applying the charging voltage from the power supply to the output end of the differential amp by using the switching element when an inputted switching signal represents a power down state of the differential amp; and stopping the application of the charging voltage to the output end of the differential amp by using the switching element when the inputted switching signal represents a steady operation state.

According to the first, second and fourth aspects, in the CMOS op-amp circuit, the time until the CMOS op-amp circuit stabilizes to the steady state after release of the power down state can be shortened. Accordingly, the operation speed of the CMOS op-amp circuit can be increased.

According to the third aspect, a potential difference can be generated in both electrodes of the phase compensation capacitor because the voltage value of the charging voltage becomes smaller as a result of passing through the connected resistor. Accordingly, the charging voltage and the output voltage can be made the same.

### BRIEF DESCRIPTION OF THE DRAWINGS

Exemplary embodiments of the present invention will be described in detail based on the following figures, wherein:

FIG. 1 is a configurational diagram showing an example of the general configuration of a PMOS differential CMOS op-amp circuit in a first exemplary embodiment;

FIG. 2 is a diagram describing a specific example relationship between an enable signal, an output value of an output end OUT2, a bias voltage, an output value of an output end OUT1 and a Vin+ voltage value, during switching between a power down state and a steady operation state, in the PMOS differential CMOS op-amp circuit of the first exemplary embodiment;

FIG. 3 is a diagram describing a specific example relationship between the enable signal, the output value of the output end OUT2, the bias voltage, the output value of the output end OUT1 and the Vin+ voltage value, during switching between the power down state and the steady operation state, in the PMOS differential CMOS op-amp circuit of the first exemplary embodiment;

FIG. 4 is a diagram describing a specific example relationship between an enable signal, an output value of an output end OUT2, a bias voltage, an output value of an output end OUT1 and a Vin+ voltage value, during switching between a power down state and a steady operation state, in a conventional PMOS differential CMOS op-amp circuit;

FIG. 5 is a diagram describing a specific example relationship between the enable signal, the output value of the output end OUT2, the bias voltage, the output value of the output end OUT1 and the Vin+ voltage value, during switching between the power down state and the steady operation state, in the conventional PMOS differential CMOS op-amp circuit;

FIG. 6 is a diagram describing an example relationship between the output value of the output end OUT2 of the first exemplary embodiment and the output value of the conventional output end OUT2;

FIG. 7 is a configurational diagram showing an example of the general configuration of a PMOS differential CMOS op-amp circuit in a second exemplary embodiment;

FIG. 8 is an diagram describing an example of the relationship between the output values of the output ends OUT2 of the first exemplary embodiment and the second exemplary embodiment and the output value of the conventional output end OUT2;

FIG. 9 is a configurational diagram showing an example of the general configuration of an NMOS differential CMOS op-amp circuit in a third exemplary embodiment;

FIG. 10 is a diagram describing an example relationship between the output value of the output end OUT2 of the third exemplary embodiment and the output value of the conventional output end OUT2;

FIG. 11 is a configurational diagram showing an example of the general configuration of the conventional PMOS differential CMOS op-amp circuit; and

FIG. 12 is a configurational diagram showing an example of an amplifier circuit that uses the CMOS op-amp circuit.

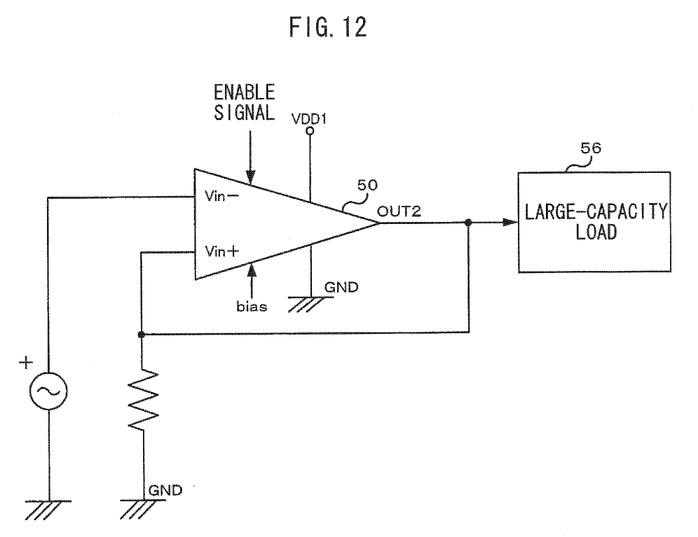

### DETAILED DESCRIPTION OF THE INVENTION

### First Exemplary Embodiment

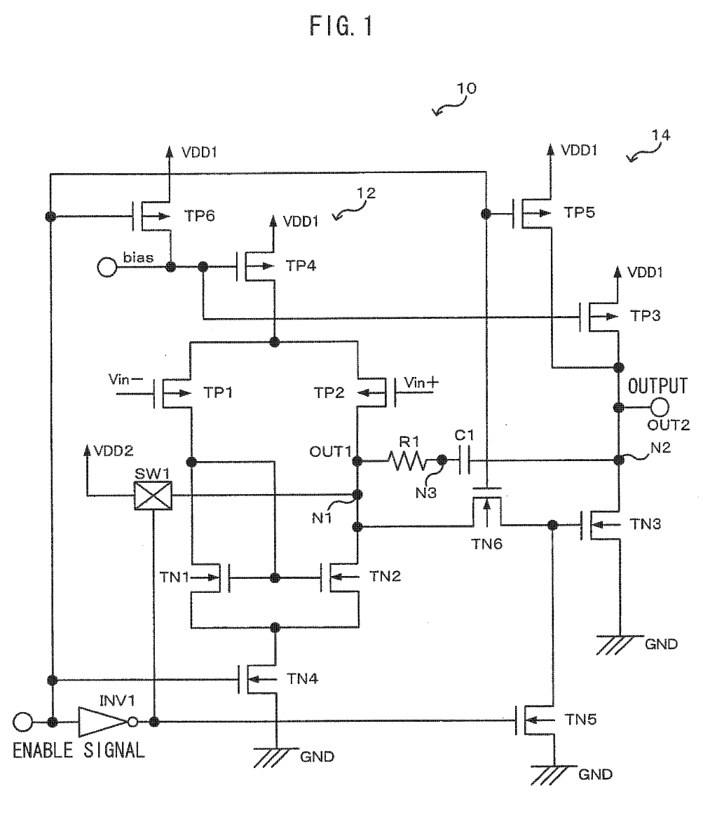

Below, a first exemplary embodiment of the present invention will be described in detail with reference to the drawings. FIG. 1 is a configurational diagram showing an example of the general configuration of an op-amp circuit 10 in the present exemplary embodiment. Note that, in the present exemplary embodiment, a case will be described where the op-amp circuit 10 is a PMOS differential CMOS op-amp circuit.

First, the configuration of the PMOS differential CMOS op-amp circuit 10 of the present exemplary embodiment will be described. As shown in FIG. 1, the PMOS differential CMOS op-amp circuit 10 of the present exemplary embodiment is configured to include a differential amp 12, an output circuit 14, a switching element SW1, a resistor R1 and a phase compensation capacitor C1.

The differential amp 12 is configured to include P-channel differential MOS transistors TP1 and TP2, N-channel MOS transistors TN1 and TN2, a bias setting MOS transistor TP4 and a ground (GND) setting MOS transistor TN4.

The output circuit 14 is configured to include P-channel output transistors TP3 and TP5, an N-channel output transistor TN3 (output switch element) and an N-channel output transistor TN5.

The switching element SW1 is switched ON when an “H” level signal is inputted thereto. Next, a voltage VDD2 (charging voltage) that is smaller than a voltage VDD1 is applied to a node N1 that is a connection point between the P-channel MOS transistor TP2 and the N-channel MOS transistor. Note that, the voltage VDD2 is a voltage (drive voltage) that is higher than a threshold value of the N-channel MOS transistor TN3. The voltage VDD2 may be supplied from a power supply that is disposed separately from the voltage VDD1. On the other hand, the voltage VDD2 may be generated from the voltage VDD1 inside the PMOS differential CMOS op-amp circuit 10.

Further, the switching element SW1 is switched OFF when an “L” level signal is inputted thereto. Specific examples of the switching element SW1 may be a coupling transistor or the like.

The resistor R1 and the phase compensation capacitor C1 are connected in series and are disposed between an output end OUT1 of the differential amp 12 and a node N2 of the output circuit 14.

Next, operation of the PMOS differential CMOS op-amp circuit 10 of the present exemplary embodiment will be described.

The PMOS differential CMOS op-amp circuit 10 of the present exemplary embodiment reaches a power down (low power consumption mode) state when an enable signal (power down control signal) is an “L” level. On the other hand, the PMOS differential CMOS op-amp circuit 10 operates in a steady state when the enable signal is an “H” level. Note that, a bias voltage is an “H” level during power down and becomes “L” (drive voltage of the P-channel MOS transistors TP3 and TP4) during steady operation.

First, operation during power down will be described. During power down, an “L” level enable signal is inputted, the P-channel MOS transistor TP6 switches ON, the P-channel MOS transistor TP4 switches OFF and the N-channel MOS transistor TN4 switches OFF. Due thereto, the differential amp 12 does not operate. Further, the P-channel MOS transistor TP3 switches OFF, the P-channel MOS transistor TP5 switches ON and the N-channel MOS transistor TN6 switches OFF. Further, because of a signal (“H” level signal) that has been inverted by and outputted from an inverter INV1, the N-channel MOS transistor TN5 switches ON and the N-channel MOS transistor TN3 switches OFF.

Due thereto, during power down, the voltage VDD1 is outputted from an output end OUT2.

The switching element SW1 is switched ON by an “H” level signal that has been inverted by and outputted from the inverter INV1 and applies the voltage VDD2 to the node N1. The voltage VDD2 that has been applied is outputted from the output end OUT1, passes through the resistor R1 and is applied to the phase compensation capacitor C1. As a result of having passed through the resistor R1, the voltage (voltage of a node N3) that is applied to electrodes of the phase compensation capacitor C1 becomes smaller than VDD2. On the other hand, the electric potential of the electrode on the node 2 side is the output value of VDD1, so an electric potential difference arises between both electrodes of the phase compensation capacitor C1 and an electric charge is accumulated.

Next, operation during steady operation will be described. During steady operation, an “H” level enable signal is inputted, the P-channel MOS transistor TP6 switches OFF, the P-channel MOS transistor TP4 switches ON and the N-channel MOS transistor TN4 switches ON. Accordingly, the differential amp 12 operates. Further, the P-channel MOS transistor TP3 switches ON, the P-channel MOS transistor TP5 switches OFF and the N-channel MOS transistor TN6 switches ON. Further, because of a signal (“L” level signal) that has been inverted by and outputted from the inverter INV1, the N-channel MOS transistor TN5 switches OFF and the N-channel MOS transistor TN3 switches ON.

Accordingly, during steady operation, voltage values corresponding to Vin+ and Vin− are outputted from the output end OUT2.

The switching element SW1 is switched OFF by an “L” level signal that has been inverted by and outputted from the inverter INV1. Application of voltage to the electrode on the output end OUT1 side of the phase compensation capacitor C1 stops. Due thereto, the electric charge that had been accumulated in the phase compensation capacitor C1 is discharged. As soon as the PMOS differential CMOS op-amp circuit 10 switches from the power down state to the steady operation state, an electric charge corresponding to the voltage that had been applied between both electrodes is accumulated in the phase compensation capacitor C1. Accordingly, the electric charge of the phase compensation capacitor C1 is discharged and flows to a gate of the N-channel MOS transistor TN3. Next, the gate of the N-channel MOS transistor TN3 instantaneously switches ON, and rapidly reduces the output value of the output end OUT2 to a ground level.

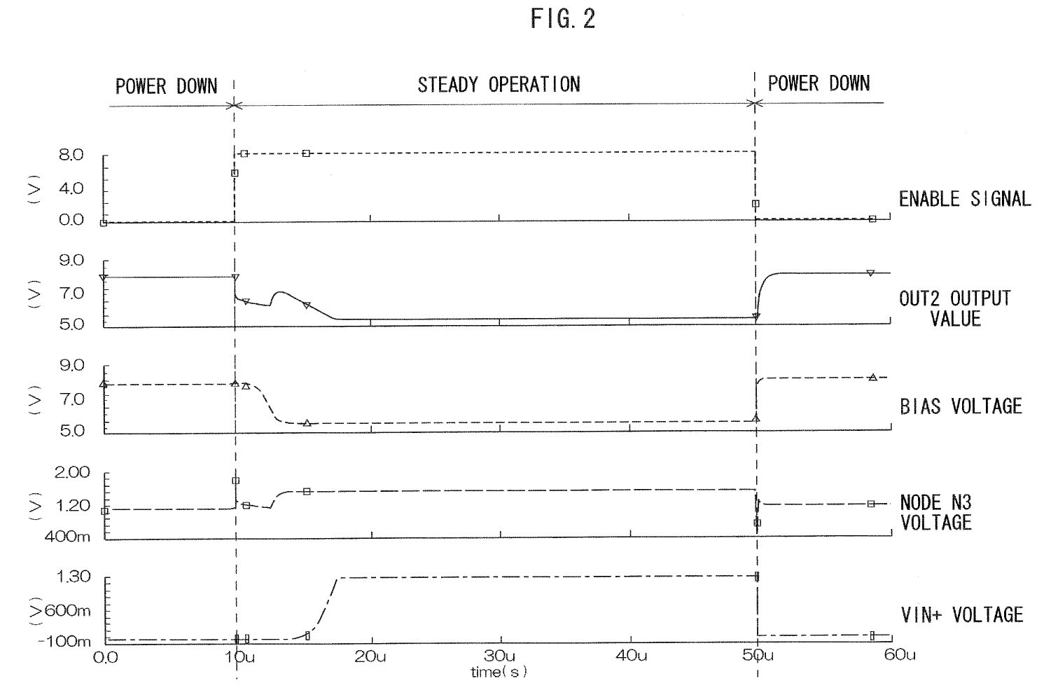

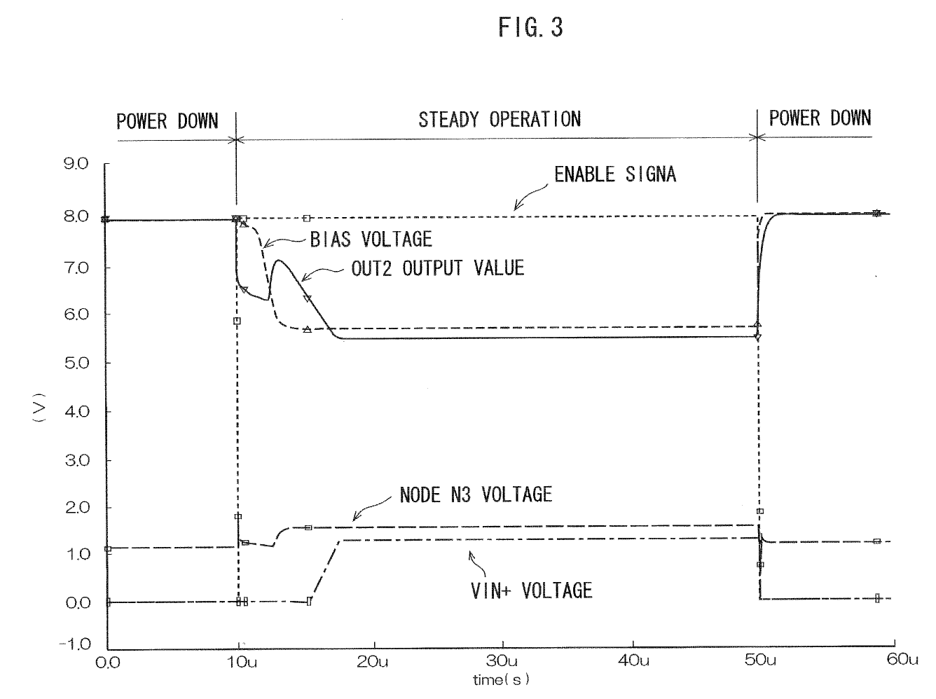

FIG. 2 and FIG. 3 show a specific example relationship between the enable signal, the output value of the output end OUT2, the bias voltage, the voltage of the node N3 and the Vin+ voltage value, during switching between the power down state and the steady operation state, in the PMOS differential CMOS op-amp circuit 10 of the present exemplary embodiment. Here, as a specific example, the voltage of VDD1 is set as 8 V and the voltage of VDD2 is set as 3 V. Note that, although the voltage of VDD2 is set as 3 V, the voltage of the node N3 during power down becomes 1.2 V because of the resistor R1. Due thereto, an electric charge can be accumulated in the phase compensation capacitor C1.

As shown in FIG. 2 and FIG. 3, the output value of the output end OUT2 precipitously falls immediately after the PMOS differential CMOS op-amp circuit 10 switches from the power down state to the steady operation state. Thereafter, voltage values corresponding to Vin+ and Vin− are outputted from the output end OUT2.

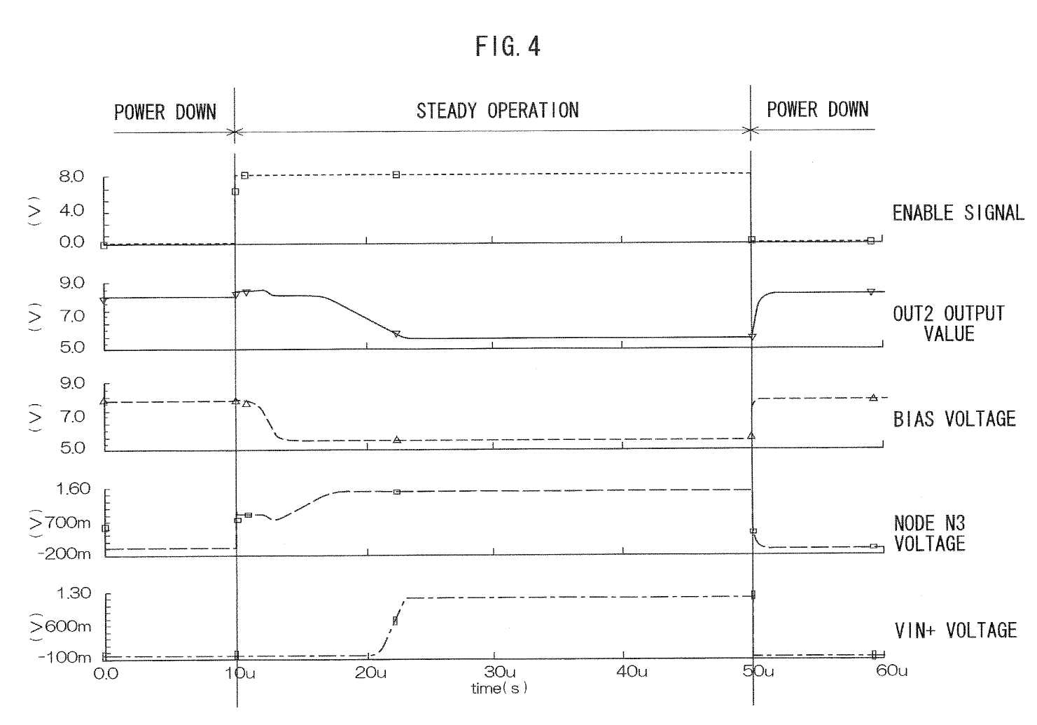

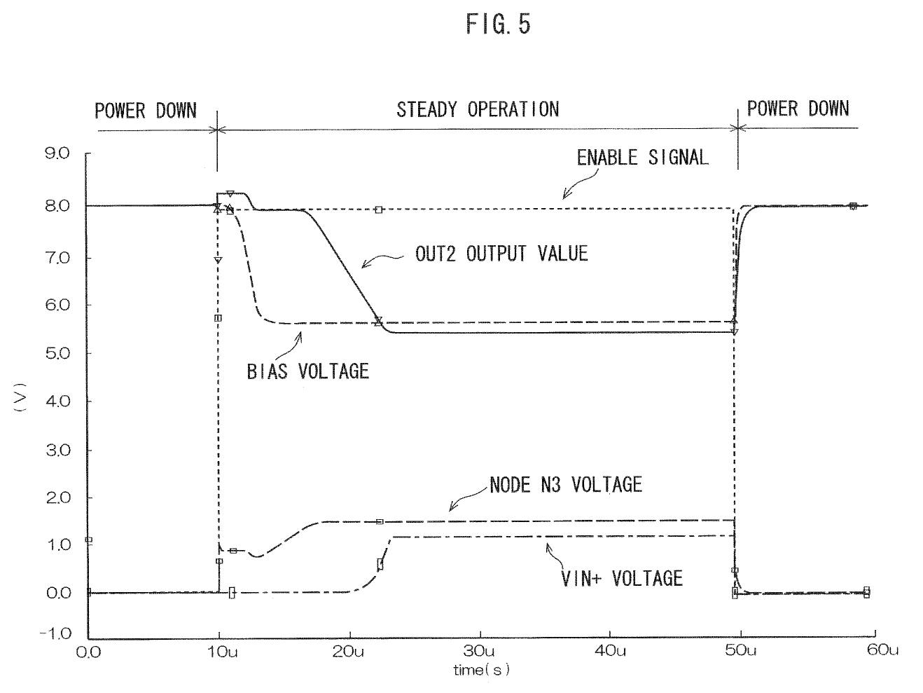

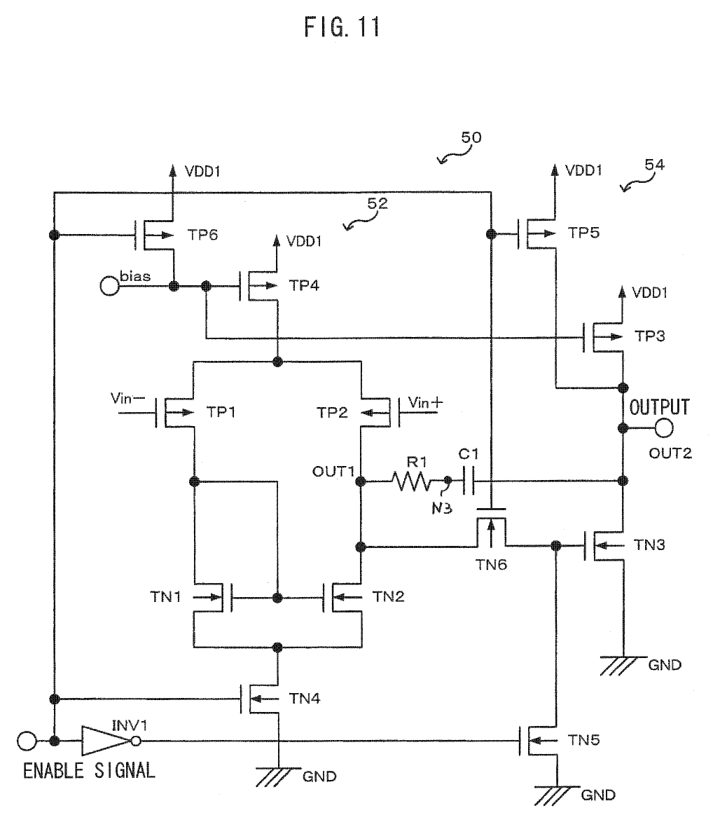

Here, FIG. 4 and FIG. 5 show a specific example relationship between the enable signal, the output value of the output end OUT2, the bias voltage, the voltage of the node N3 and the Vin+ voltage value, during switching between the power down state and the steady operation state, in the conventional PMOS differential CMOS op-amp circuit 50 (see FIG. 11). As shown in FIG. 4 and FIG. 5, the output value of the output end OUT2 slowly falls soon after the conventional PMOS differential CMOS op-amp circuit 50 is switched from the power down state to the steady operation state. Thereafter, the output value of the output end OUT2 becomes voltage values corresponding to Vin+ and Vin−.

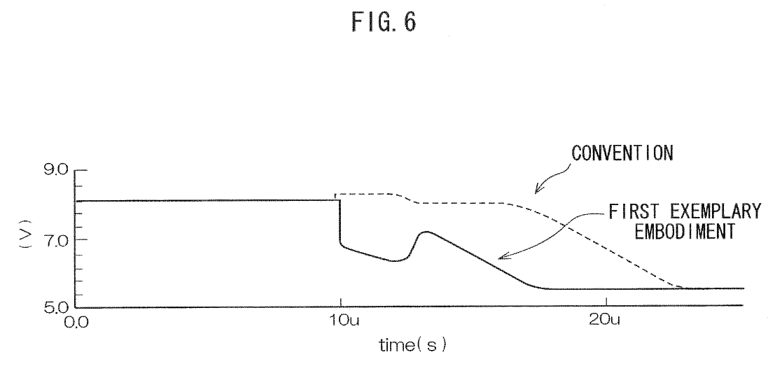

FIG. 6 shows the relationship between the output value of the output end OUT2 of the present exemplary embodiment, and the output value of the conventional output end OUT2. As shown in FIG. 6, it will be understood that, in comparison to convention, the output (OUT2 output value) of the PMOS differential CMOS op-amp circuit 10 of the present exemplary embodiment quickly becomes stable after when the PMOS differential CMOS op-amp circuit 10 is switched to the steady operation state.

Note that, the time (operating speed after power down release) until the output becomes stable after when the PMOS differential CMOS op-amp circuit 10 is switched to the steady operation state can be adjusted by the value of the voltage of VDD2.

Note that, in the present exemplary embodiment, the resistor R1 is disposed. However, the PMOS differential CMOS op-amp circuit 10 may also be given a configuration where the resistor R1 is not disposed, because the voltage VDD2 is smaller than the voltage VDD1.

As described above, according to the PMOS differential CMOS op-amp circuit 10 of the present exemplary embodiment, the voltage VDD2 is applied by SW1 during power down. Due thereto, an electric potential difference arises between both electrodes of the phase compensation capacitor C1 and an electric charge can be accumulated. Consequently, when the PMOS differential CMOS op-amp circuit 10 switches to the steady state, the electric charge that had been accumulated in the phase compensation capacitor C1 is discharged and the gate of the N-channel MOS transistor TN3 switches ON. Due thereto, instantaneously the output value of the output end OUT2 settles into a stable state after it has been reduced. Accordingly, the amount of time until the output value of the output end OUT2 stabilizes to the steady state, after release of the power down state, can be shortened. Thus, the operating speed of the op-amp circuit 10 can be increased.

### Second Exemplary Embodiment

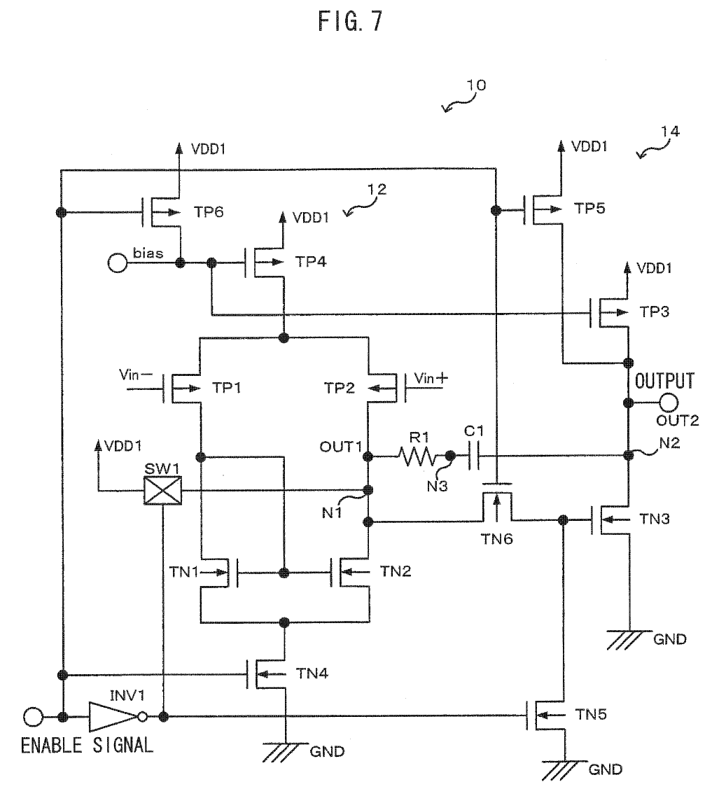

Next, a second exemplary embodiment of the present invention will be described in detail with reference to the drawings. FIG. 7 is a configurational diagram showing an example of the general configuration of an op-amp circuit 10 pertaining in the present exemplary embodiment. In the present exemplary embodiment, the switching element SW1 of the first exemplary embodiment controls (ON, OFF) to apply the voltage VDD1 that is a source voltage of the P-channel differential MOS transistors TP1 to TP6. Consequently, the op-amp circuit 10 of the second exemplary embodiment has the same configuration and operation as the first exemplary embodiment, except that the voltage value applied from the switching element SW1 is the voltage of VDD1. Thus, the same reference numerals will be given to the same portions and detailed description will be omitted.

Note that, in the present exemplary embodiment, the same power supply can be used for the power supply of the VDD1 voltage, that is applied from the switching element SW1 and the power supply of the source voltage of the P-channel differential MOS transistors TP1 to TP6.

In the present exemplary embodiment, during power down, the switched element SW1 is switched ON by an “H” level signal that has been inverted by and outputted from the inverter INV1 and applies the voltage VDD1 to the node N1. The voltage VDD1 that has been applied is outputted from the output end OUT1, passes through the resistor R1 and is applied to the electrodes of the phase compensation capacitor C1. As a result of passing through the resistor R1, the voltage (voltage of the node N3) that is applied to the electrodes of the phase compensation capacitor C1 becomes smaller than VDD1. On the other hand, the electric potential of the electrode on the node N2 side is the output value of VDD1. Due thereto, an electric potential difference arises between both electrodes of the phase compensation capacitor C1 and an electric charge is accumulated.

In this manner, even when a value (the voltage of VDD1) that is the same as the electric potential of the electrode on the node N2 side of the phase compensation capacitor C1 has been applied from the switching element SW1, the voltage of the node N3 becomes smaller than VDD1 as a result of passing through the resistor R1. Due thereto, an electric potential difference can be generated between both electrodes. Accordingly, an electric charge can be accumulated in the phase compensation capacitor C1.

During steady operation, the switching element SW1 is switched OFF by an “L” level signal that has been inverted by and outputted from the inverter INV1. Next, application of voltage to the electrode on the output end OUT1 side of the phase compensation capacitor C1 stops and the electric charge that had been accumulated is discharged. As soon as the op-amp circuit 10 switches from the power down state to the steady operation state, an electric charge corresponding to the voltage that had been applied between both electrodes is accumulated in the phase compensation capacitor C1. Due thereto, the electric charge of the phase compensation capacitor C1 is discharged and flows to the gate of the N-channel MOS transistor TN3. Next, the gate of the N-channel MOS transistor TN3 instantaneously switches ON and rapidly reduces the output value of the output end OUT2 to a ground level. Thereafter, voltage values corresponding to Vin+ and Vin− are outputted from the output end OUT2.

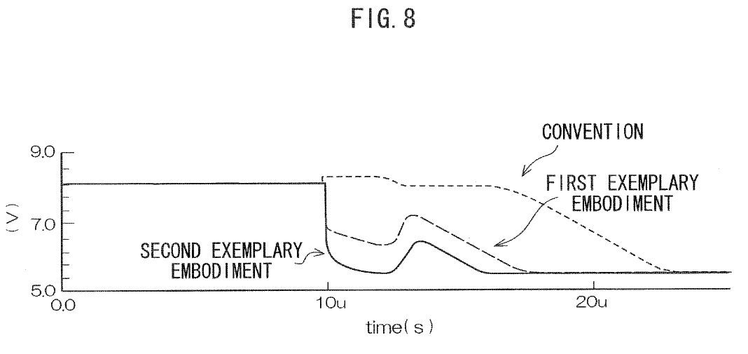

FIG. 8 shows the relationship between the output value of the output end OUT2 of the present exemplary embodiment, the output value of the output end OUT2 of the first exemplary embodiment and the output value of the conventional output end OUT2. As shown in FIG. 8, it will be understood that, in comparison to the first exemplary embodiment, the output value of the output end OUT2 of the op-amp circuit 10 of the present exemplary embodiment largely drops and quickly becomes stable after when the op-amp circuit 10 of the present exemplary embodiment is switched to the steady operation state.

In this manner, in the present exemplary embodiment, in comparison to the voltage of VDD2 in the first exemplary embodiment, an electric charge is accumulated in the phase compensation capacitor C1 because of the large voltage VDD1. Due thereto, after the op-amp circuit 10 is switched from the power down state to the steady operation state, the output value of the output end OUT2 drops precipitously and quickly becomes stable than in the first exemplary embodiment.

Note that, in this manner, the time (operating speed after power down release) until the output becomes stable after the op-amp circuit 10 is switched to the steady operation state can be adjusted by the voltage value (voltage value of the node N3) of the voltage that is applied by the switching element SW1.

As described above, according to the PMOS differential CMOS op-amp circuit 10 of the present exemplary embodiment, the voltage of VDD1 is applied by SW1 during power down, and the voltage value of the node N3 falls lower than the voltage of VDD1, because of the resistor R1. Due thereto, an electric potential difference arises between both electrodes of the phase compensation capacitor C1 and an electric charge can be accumulated. When the PMOS differential CMOS op-amp circuit 10 is switched to the steady state, the electric charge that had been accumulated in the phase compensation capacitor C1 is discharged and the gate of the N-channel MOS transistor TN3 switches ON. Due thereto, the output value of the output end OUT2 instantaneously settles into a stable state after it has been reduced. Accordingly, the time until the output value of the output end OUT2 stabilizes to the steady state after release of the power down state can be shortened. Thus, the operating speed of the op-amp circuit 10 can be increased.

Further, because the voltage VDD1 is applied, the amount of time until the output value of the output end OUT2 stabilizes to the steady state can be shortened even more. Thus, the operating speed of the op-amp circuit 10 can be increased even more.

### Third Exemplary Embodiment

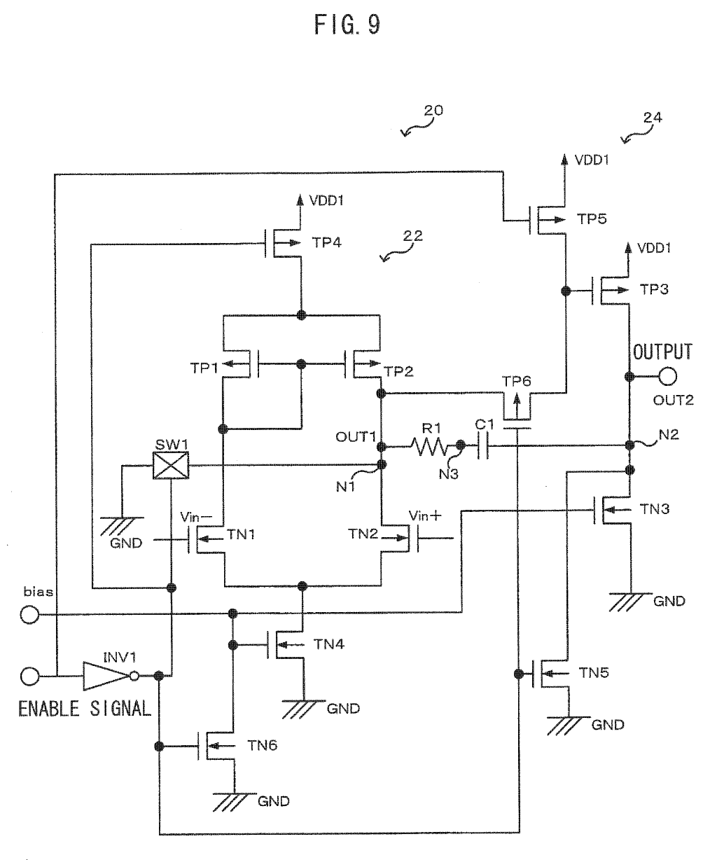

Next, a third exemplary embodiment of the present invention will be described in detail with reference to the drawings. FIG. 9 is a configurational diagram showing an example of the general configuration of an op-amp circuit 20 pertaining in the present exemplary embodiment. Note that, in the present exemplary embodiment, a case will be described where the op-amp circuit 20 is an NMOS differential CMOS op-amp circuit.

First, the configuration of the NMOS differential CMOS op-amp circuit 20 of the present exemplary embodiment will be described. As shown in FIG. 9, the NMOS differential CMOS op-amp circuit 20 of the present exemplary embodiment is configured to include a differential amp 22, an output circuit 24, a switching element SW1, a resistor R1 and a phase compensation capacitor C1.

The differential amp 22 is configured to include N-channel differential MOS transistors TN1 and TN2, P-channel MOS transistors TP1 and TP2, a bias setting MOS transistor TP4 and a ground (GND) setting MOS transistor TN4.

The output circuit 24 is configured to include P-channel output transistors TP3 and TP5, an N-channel output transistor TN3 (output switch element) and an N-channel output transistor TN5.

The switching element SW1 is switched ON when an “H” level signal is inputted thereto. Next, a GND voltage (charging voltage) is applied to a node N1 that is a connection point between the P-channel MOS transistor TP2 and the N-channel MOS transistor. Further, the switching element SW1 is switched OFF when an “L” level signal is inputted thereto. Specific examples of the switching element SW1 may be a coupling transistor or the like.

The resistor R1 and the phase compensation capacitor C1 are connected in series and are disposed between an output end OUT1 of the differential amp 22 and a node N2 of the output circuit 24.

Next, operation of the NMOS differential CMOS op-amp circuit 20 of the present exemplary embodiment will be described.

The NMOS differential CMOS op-amp circuit 20 of the present exemplary embodiment reaches a power down (low power consumption mode) state when an enable signal (power down control signal) is an “L” level. On the other hand, the NMOS differential CMOS op-amp circuit 20 operates in a steady state when the enable signal is an “H” level. Note that, a bias voltage is an “L” level during power down and becomes “H” (drive voltage of the N-channel MOS transistors TN3 and TN4) during steady operation.

First, operation during power down will be described. During power down, an “L” level enable signal is inputted, the P-channel MOS transistor TP5 switches ON and the P-channel MOS transistor TP3 switches OFF. Further, because of a signal (“H” level signal) that has been inverted by and outputted from an inverter INV1, the P-channel MOS transistor TP4 switches OFF and the N-channel MOS transistor TN6 switches ON. The bias voltage is an “L” level and the N-channel MOS transistor TN4 switches OFF. Due thereto, the differential amp 22 does not operate. Further, the P-channel MOS transistor TP6 switches OFF, the N-channel MOS transistor TN5 switches ON, and the N-channel MOS transistor TN3 switches OFF.

Due thereto, during power down, the output of an output end OUT2 becomes the GND voltage.

The switching element SW1 is switched ON by an “H” level signal that has been inverted by and outputted from the inverter INV1 and applies the GND voltage to the node N1. The GND voltage that has been applied is outputted from the output end OUT1, passes through the resistor R1 and is applied to electrodes of the phase compensation capacitor C1. As a result of having passed through the resistor R1, the voltage that is applied to the electrodes of the phase compensation capacitor C1 becomes smaller than the GND voltage. On the other hand, the electric potential of electrode on the node 2 side is the output value GND. Due thereto, an electric potential difference arises between both electrodes of the phase compensation capacitor C1 and an electric charge can be accumulated in the phase compensation capacitor C1.

Next, operation during steady operation will be described. During steady operation, an “H” level enable signal is inputted, the P-channel MOS transistor TP5 switches OFF and the P-channel MOS transistor TP3 switches ON. Further, because of a signal (“L” level signal) that has been inverted by and outputted from the inverter INV1, the P-channel MOS transistor TP4 switches ON and the N-channel MOS transistor TN6 switches OFF. The bias voltage is an “H” level and the N-channel MOS transistor TN4 switches ON. Due thereto, the differential amp 22 operates. Further, the P-channel MOS transistor TP6 switches ON, the N-channel MOS transistor TN5 switches OFF and the N-channel MOS transistor TN3 switches ON.

Due thereto, during steady operation, voltage values corresponding to Vin+ and Vin− are outputted from the output end OUT2.

The switching element SW1 is switched OFF by an “L” level signal that has been inverted by and outputted from the inverter INV1. Application of voltage to the electrode on the output end OUT1 side of the phase compensation capacitor C1 stops and the electric charge that had been accumulated is discharged. As soon as the NMOS differential CMOS op-amp circuit 20 is switched from the power down state to the steady operation state, an electric charge corresponding to the voltage that had been applied between both electrodes is accumulated in the phase compensation capacitor C1. Due thereto, the electric charge is discharged and flows to a gate of the P-channel MOS transistor TP3. The gate of the P-channel MOS transistor TP3 instantaneously switches ON. Accordingly, the output value of the output end OUT2 is rapidly reduced to the VDD1 level.

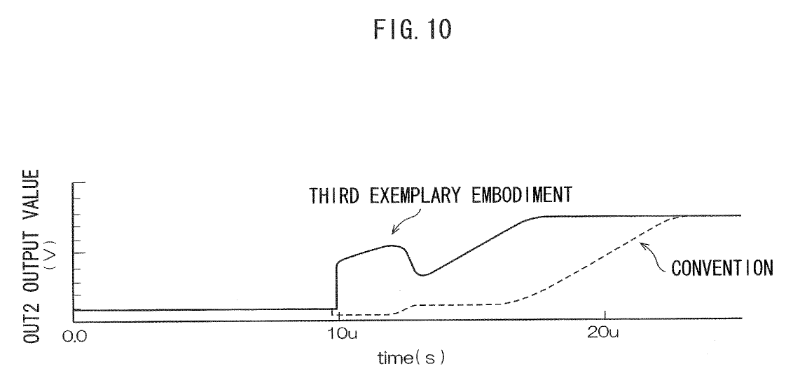

FIG. 10 shows the relationship between the output value of the output end OUT2 of the present exemplary embodiment and the output value of an output end OUT2 of a conventional NMOS differential CMOS op-amp circuit (a circuit in a case where the GND voltage is not applied by the switching element SW1; not shown). As shown in FIG. 10, it will be understood that, in comparison to convention, the output (OUT2 output value) of the NMOS differential CMOS op-amp circuit 20 of the present exemplary embodiment quickly becomes stable after the NMOS differential CMOS op-amp circuit 20 is switched to the steady operation state.

As described above, according to the NMOS differential CMOS op-amp circuit 20 of the present exemplary embodiment, the GND voltage is applied by SW1 during power down. Due thereto, an electric potential difference arises between both electrodes of the phase compensation capacitor C1 and an electric charge can be accumulated. Consequently, when the NMOS differential CMOS op-amp circuit 20 switches to the steady state, the electric charge that had been accumulated in the phase compensation capacitor C1 is discharged and the gate of the P-channel MOS transistor TP3 switches ON. Accordingly, the output value of the output end OUT2 instantaneously settles into a stable state after it has been reduced. Consequently, the time until the output value of the output end OUT2 stabilizes to the steady state after release of the power down state can be shortened. Thus, the operating speed of the op-amp circuit 20 can be increased.

What is claimed is:

1. An op-amp circuit comprising:
a differential amp;
a CMOS output circuit;
a phase compensation capacitor disposed between an output end of the differential amp and the CMOS output circuit; and
a switching element disposed between the phase compensation capacitor and a power supply that supplies a charging voltage for charging the phase compensation capacitor,
wherein the switching element applies the charging voltage from the power supply to the output end of the differential amp when an inputted switching signal represents a power down state of the differential amp, and stops the application of the charging voltage to the output end of the differential amp when the inputted switching signal represents a steady operation state.

2. The op-amp circuit of claim 1, wherein:
the CMOS output circuit includes an output switch element including a gate terminal connected to the output end of the differential amp and a drain terminal connected to a side that outputs an output voltage that is different from the charging voltage and to the CMOS output circuit side of the phase compensation capacitor; and
the charging voltage is lower than the output voltage.

3. The op-amp circuit of claim 1, further comprising a resistor connected between the phase compensation capacitor and the differential amp, wherein:
the CMOS output circuit includes an output switch element including a gate terminal connected to the output end of the differential amp and a drain terminal connected to a side that outputs an output voltage that is different from the charging voltage and to the CMOS output circuit side of the phase compensation capacitor; and
the charging voltage and the output voltage are the same.

4. A method of driving an op-amp circuit that includes a differential amp, a CMOS output circuit, a phase compensation capacitor disposed between an output end of the differential amp and the CMOS output circuit, and a switching element disposed between the phase compensation capacitor and a power supply that supplies a charging voltage for charging the phase compensation capacitor, the method comprising:
applying the charging voltage from the power supply to the output end of the differential amp by using the switching element when an inputted switching signal represents a power down state of the differential amp; and
stopping the application of the charging voltage to the output end of the differential amp by using the switching element when the inputted switching signal represents a steady operation state.
